(19) United States
(12) Patent Application Publication
(10) Pub. No.: US 2011/0209995 A1
(43) Pub. Date: Sep. 1, 2011

(54) Physical Vapor Deposition With A Variable Capacitive Tuner and Feedback Circuit

(75) Inventors: Muhammad M. Rasheed, San Jose, CA (US); Ronald D. DeDore, Scotts Valley, CA (US); Michael S. Cox, San Jose, CA (US); Keith A. Miller, Mountain View, CA (US); Donny Young, San Jose, CA (US); John C. Forster, San Francisco, CA (US); Adolph M. Allen, Oakland, CA (US); Lara Hawrylchak, San Jose, CA (US)

(73) Assignee: Applied Materials, Inc., Santa Clara, CA (US)

(21) Appl. No.: 12/823,893

(22) Filed: Jun. 25, 2010

Related U.S. Application Data
(60) Provisional application No. 61/309,372, filed on Mar. 1, 2010.

(51) Int. Cl. C23C 14/34

(52) U.S. Cl. 204/298.08; 204/298.38

(57) ABSTRACT

Apparatus and methods for performing plasma processing on a wafer supported on a pedestal are provided. The apparatus can include a pedestal on which the wafer can be supported, a variable capacitor having a variable capacitance, a motor attached to the variable capacitor which varies the capacitance of the variable capacitor, a motor controller connected to the motor that causes the motor to rotate, and an output from the variable capacitor connected to the pedestal. A desired state of the variable capacitor is associated with a process recipe in a process controller. When the process recipe is executed the variable capacitor is placed in the desired state.

### STATEMENT OF RELATED CASES

This application claims the benefit of U.S. Provisional Patent Application Ser. No. 61/309,372 filed on Mar. 1, 2010, which is incorporated herein by reference in its entirety.

### BACKGROUND

Plasma processing is employed in fabrication of integrated circuits, masks for use in photolithographic processing of integrated circuits, plasma displays and solar technology, for example. In the fabrication of integrated circuits, a semiconductor wafer is processed in a plasma chamber. The process may be a reactive ion etch (RIE) process, a plasma enhanced chemical vapor deposition (PECVD) process or a plasma enhanced physical vapor deposition (PEPVD) process, for example. Recent technological advances in integrated circuits have reduced feature sizes to less than 32 nanometers. Further reductions will require more precise control over process parameters at the wafer surface, including plasma ion energy spectrum, plasma ion energy radial distribution (uniformity), plasma ion density and plasma ion density radial distribution (uniformity). In addition, better consistency in such parameters between reactors of identical design is required. Ion density is important in PEPVD processes, for example, because ion density at the wafer surface determines deposition rate and the competing etch rate. At the target surface, target consumption (sputtering) rate is affected by ion density at the target surface and ion energy at the target surface.

The ion density radial distribution and the ion energy radial distribution across the wafer surface can be controlled by impedance tuning of a sputtering frequency dependent power source. There is a need to set at least one tuning parameter for impedance control in a repeatable manner based on a measured process parameter.

### SUMMARY

A plasma reactor is provided for performing physical vapor deposition on a workpiece such as a semiconductor wafer. The reactor includes a chamber including a side wall and a ceiling, the side wall being coupled to an RF ground.

A workpiece support is provided within the chamber having a support surface facing the ceiling and a bias electrode underlying the support surface. A sputter target is provided at the ceiling with an RF source power supply of frequency fₛ coupled to the sputter target. An RF bias power supply of frequency f_{b} is coupled to the bias electrode. A first multi-frequency impedance controller is coupled between RF ground and one of (a) the bias electrode, (b) the sputter target, the controller providing adjustable impedances at a first set of frequencies, the first set of frequencies including a first set of frequencies to be blocked and a first set of frequencies to be admitted. The first multi-frequency impedance controller includes a set of band pass filters connected in parallel and tuned to the first set of frequencies to be admitted, and a set of notch filters connected in series and tuned to the first set of frequencies to be blocked.

In one embodiment, the band pass filters comprise inductive and capacitive elements connected in series, while the notch filters comprise inductive and capacitive components connected in parallel. The capacitive elements of the band pass filter and of the notch filters are variable in accordance with one embodiment.

The reactor may further include a second multi-frequency impedance controller coupled between the bias electrode and RF ground and providing adjustable impedances at a second set of frequencies, the first set of frequencies comprising at least the source supply frequency fₛ. The first set of frequencies are selected from a set of frequencies that includes harmonics of fₛ, harmonics of f_{b}, and intermodulation products of fₛ and f_{b}, in one embodiment.

In accordance with a further aspect of the present invention, an automatic, motor-driven, variable capacitive tuner circuit for plasma processing apparatus is provided. The circuit can have a processor controlled feedback circuit is provided to tune and match ion energy on the wafer for a given setpoint (voltage, current, positional etc.), thereby allowing process results to be matched from chamber to chamber and resulting in improved wafer processing.

In accordance with another aspect of the present invention, a physical vapor deposition plasma reactor is provided, comprising a chamber including a side wall and a ceiling, said side wall being coupled to an RF ground, a workpiece support within the chamber having a support surface facing the ceiling and a bias electrode underlying the support surface, a sputter target at said ceiling, an RF source power supply of a first frequency coupled to said sputter target, and an RF bias power supply of a second frequency coupled to said bias electrode, a multi-frequency impedance controller coupled between RF ground and one of (a) the bias electrode, and providing at least a first adjustable impedance at a first set of frequencies, said multi-frequency impedance controller comprising a variable capacitor enabled to be placed in at least one of two states by a motor, the at least two states of the variable capacitor having different capacitances.

In accordance with yet another aspect of the present invention, the physical vapor deposition plasma reactor is provided, wherein the multi-frequency impedance controller further comprises an inductive element connected in series with the variable capacitor.

In accordance with yet another aspect of the present invention, the physical vapor deposition plasma reactor is provided, wherein the multi-frequency impedance controller further comprises a processor to control the motor of the variable capacitor.

In accordance with yet another aspect of the present invention, the physical vapor deposition plasma reactor is provided, wherein the multi-frequency impedance controller further comprises a current sensor to control the motor of the variable capacitor.

In accordance with yet another aspect of the present invention, the physical vapor deposition plasma reactor is provided, wherein the multi-frequency impedance controller further comprises a voltage sensor to control the motor of the variable capacitor.

In accordance with yet another aspect of the present invention, the physical vapor deposition plasma reactor is provided, wherein a state of the variable capacitor is associated with a process recipe in a process controller.

In accordance with yet another aspect of the present invention, the physical vapor deposition plasma reactor is provided, further comprising a housing for the variable capacitor.

In accordance with yet another aspect of the present invention, the physical vapor deposition plasma reactor is provided, wherein an output of the variable capacitor is connected to the housing.

In accordance with yet another aspect of the present invention, the physical vapor deposition plasma reactor is provided, wherein the housing is connected to ground.

In accordance with yet another aspect of the present invention, the physical vapor deposition plasma reactor is provided, wherein the process recipe is a common process recipe adjusted for a chamber-to-chamber variation.

In accordance with a further aspect of the present invention, a plasma reactor is provided, comprising a chamber including a side wall and a ceiling, said side wall being coupled to an RF ground, the chamber sustaining a plasma for material deposition, a workpiece support within the chamber having a support surface facing the ceiling and a bias electrode underlying the support surface, a source power applicator at said ceiling, an RF source power supply of a first frequency coupled to said source power applicator, and an RF bias power supply of a second frequency coupled to said bias electrode, a multi-frequency impedance controller coupled between RF ground and the bias electrode, and providing at least a first adjustable impedance at a first set of frequencies, said multi-frequency impedance controller comprising a variable capacitor enabled to be placed in at least one of two states by a motor, the at least two states of the variable capacitor having different capacitances.

In accordance with yet a further aspect of the present invention, a plasma reactor is provided, wherein the multi-frequency impedance controller further comprises an inductive element connected in series with the variable capacitor.

In accordance with yet a further aspect of the present invention, a plasma reactor is provided, wherein the multi-frequency impedance controller further comprises a processor to control the motor of the variable capacitor.

In accordance with yet a further aspect of the present invention, a plasma reactor is provided, wherein the multi-frequency impedance controller further comprises a current sensor to control the motor of the variable capacitor.

In accordance with yet a further aspect of the present invention, a plasma reactor is provided, wherein the multi-frequency impedance controller further comprises a voltage sensor to control the motor of the variable capacitor.

In accordance with yet a further aspect of the present invention, a plasma reactor is provided, wherein a state of the variable capacitor is associated with a process recipe in a process controller.

In accordance with yet a further aspect of the present invention, a plasma reactor is provided, further comprising a housing for the variable capacitor.

In accordance with yet a further aspect of the present invention, a plasma reactor is provided, wherein an output of the variable capacitor is connected to the housing.

In accordance with yet a further aspect of the present invention, a plasma reactor is provided, wherein the housing is connected to ground.

In accordance with yet a further aspect of the present invention, a plasma reactor is provided, wherein the process recipe is a common process recipe adjusted for a chamber-to-chamber variation.

### BRIEF DESCRIPTION OF THE DRAWINGS

So that the manner in which the exemplary embodiments of the present invention are attained and can be understood in detail, a more particular description of the invention, briefly summarized above, may be had by reference to the embodiments thereof which are illustrated in the appended drawings. It is to be appreciated that certain well known processes are not discussed herein in order to not obscure the invention.

FIG. 1 depicts a plasma reactor in accordance with a first embodiment.

FIG. 2 depicts the structure of multi-frequency impedance controllers in the reactor of FIG. 1.

FIG. 3 depicts a circuit implementation of a target multi-frequency impedance controller of FIG. 2.

FIG. 4 depicts a circuit implementation of a pedestal multi-frequency impedance controller of FIG. 2.

FIG. 5 depicts one embodiment if the target and pedestal multi-frequency impedance controllers.

FIG. 6 is a block diagram depicting a first method in accordance with one embodiment.

FIG. 7 depicts the different ground return paths for RF bias power controlled by a target multi-frequency impedance controller in the reactor of FIG. 1.

FIG. 8 depicts the different ground return paths for RF source power controlled by a cathode multi-frequency impedance controller in the reactor of FIG. 1.

FIG. 9 is a graph depicting different radial distributions of ion energy across a wafer or target surface that can be produced by adjusting a multi-frequency impedance controller in the reactor of FIG. 1.

FIG. 10 is a graph depicting different radial distributions of ion density across a wafer or target surface that can be produced by adjusting a multi-frequency impedance controller in the reactor of FIG. 1.

FIG. 11 is a block diagram depicting another method in accordance with one embodiment.

FIG. 12 illustrates a variable capacitor tuning circuit with a feedback circuit in accordance with one aspect of the present invention.

FIG. 13 illustrates a output circuit having selectable outputs in accordance with a further aspect of the present invention.

FIG. 14 illustrates voltage output and current output for a variable capacitor for various positions of a stepper motor that controls the variable capacitor.

FIGS. 15 to 17 illustrate processing results of fifty wafers using the variable capacitive tuner in accordance with various aspects of the present invention.

To facilitate understanding, identical reference numerals have been used, where possible, to designate identical elements that are common to the figures. It is contemplated that elements and features of one embodiment may be beneficially incorporated in other embodiments without further recitation. It is to be noted, however, that the appended drawings illustrate only exemplary embodiments of this invention and are therefore not to be considered limiting of its scope, for the invention may admit to other equally effective embodiments.

### DETAILED DESCRIPTION

In one embodiment, a first multi-frequency impedance controller is coupled between a sputter target of a PVD reactor and RF ground. Optionally, and in addition, a second multi-frequency impedance controller is coupled between the wafer susceptor or cathode and RF ground.

The first multi-frequency impedance controller (which is connected to the ceiling or sputter target) governs the ratio of the impedances to ground through the ceiling (sputter target) and the side wall. At low frequencies, this ratio affects the radial distribution of ion energy across the wafer. At very high frequencies, this ratio affects the radial distribution of ion density across the wafer.

The second multi-frequency impedance controller (which is connected to the cathode or wafer susceptor) governs the ratio of the impedances to ground through the cathode and the side wall. At low frequencies, this ratio affects the radial distribution of ion energy across the ceiling or sputter target. At very high frequencies, this ratio affects the radial distribution of ion density across ceiling or sputter target.

Each multi-frequency impedance controller governs the impedance to ground through the ceiling (in the case of the first controller) or through the cathode (in the case of the second controller) of different frequencies present in the plasma, including harmonics of the bias power frequency, harmonics of the source power frequency, inter-modulation products of the source and bias power frequencies and their harmonics, for example. The harmonics and intermodulation products may be selectively suppressed from the plasma by the multi-frequency impedance controller, in order to minimize inconsistencies in performance between reactors of the same design. It is our belief that some of these harmonics and intermodulation products are responsible for inconsistencies in reactor performance between reactors of identical design.

For very high frequencies, the first multi-frequency impedance controller's impedance to ground through the ceiling or target (with reference to the impedance through the grounded side wall) controls the radial distribution of ion density across the wafer surface is changed for fine adjustment. For low frequencies, the first multi-frequency impedance controller's impedance to ground through the ceiling or target (with reference to the impedance through the grounded side wall) controls the radial distribution of ion energy across the wafer surface is changed for fine adjustment.

For very high frequencies, the second multi-frequency impedance controller's impedance to ground through the wafer or cathode (with reference to the impedance through the grounded side wall) controls the radial distribution of ion density across the ceiling or sputter target. For low frequencies, the second multi-frequency impedance controller's impedance to ground through the wafer or cathode (with reference to the impedance through the grounded side wall) controls the radial distribution of ion energy across the sputter target or ceiling. The foregoing features provide a process control mechanism to regulate the reactor performance and uniformity.

In addition to governing distribution of ion energy and/or ion density across the wafer surface and across the ceiling (target) surface, the multi-frequency impedance controllers also govern the composite (total) ion density and ion energy at these surfaces through governance of impedance to ground at appropriate frequencies (e.g., low frequencies for ion energy and very high frequencies for ion density). Therefore, the controllers determine process rates at the wafer and target surfaces. Selected harmonics are tuned, depending upon the desired effect, either to promote their presence in the plasma or to suppress them. The tuning of the harmonics affects ion energies at wafer, thereby affecting process uniformity. In a PVD reactor, tuning of the ion energy affects step coverage, overhang geometry and physical film properties such as grain size, crystal orientation, film density, roughness and film composition. Each multiple frequency impedance controller can further be employed to enable or prevent deposition, etching or sputtering of the target or wafer or both, by appropriate adjustment of impedance to ground for selected frequencies, as will be described in detail in this specification. For example, in one mode, the target is sputtered while deposition is carried out on the wafer. In another mode, the wafer is etched while sputtering of the target is prevented, for example.

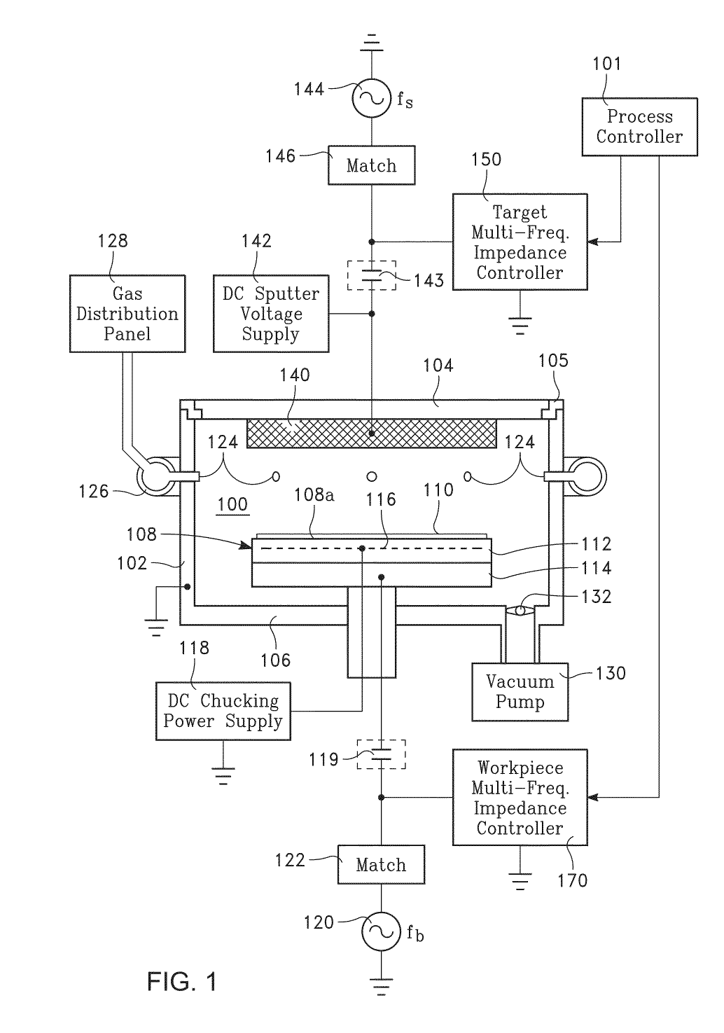

FIG. 1 depicts a PEPVD plasma reactor in accordance with a first embodiment. The reactor includes a vacuum chamber 100 enclosed by a cylindrical side wall 102, a ceiling 104 and a floor 106. A workpiece support pedestal 108 within the chamber 100 has a support surface 108a for supporting a workpiece such as a semiconductor wafer 110. The support pedestal 108 may consist of an insulating (e.g., ceramic) top layer 112 and a conductive base 114 supporting the insulating top layer 112.

A planar conductive grid 116 may be encapsulated within the top insulating layer 112 to serve as an electrostatic clamping (ESC) electrode. A D.C. clamping voltage source 118 is connected to the ESC electrode 116. An RF plasma bias power generator 120 of a bias frequency fb may be coupled through an impedance match 122 to either the ESC electrode 116 or to the conductive base 114. The conductive base 114 may house certain utilities such as internal coolant channels (not shown), for example. If the bias impedance match 122 and bias generator 120 are connected to the ESC electrode 116 instead of the conductive base 114, then an optional capacitor 119 may be provided to isolate the impedance match 122 and RF bias generator 120 from the D.C. chucking power supply 118.

Process gas is introduced into the chamber 100 by suitable gas dispersing apparatus. For example, in the embodiment of FIG. 1, the gas dispersing apparatus consists of gas injectors 124 in the side wall 102, the gas injectors being supplied by a ring manifold 126 coupled to a gas distribution panel 128 that includes various supplies of different process gases (not shown). The gas distribution panel 128 controls the mixture of process gases supplied to the manifold 126 and the gas flow rate into the chamber 100. Gas pressure in the chamber 100 is controlled by a vacuum pump 130 coupled to the chamber 100 through a pumping port 132 in the floor 106.

A PVD sputter target 140 is supported on the interior surface of the ceiling 104. A dielectric ring 105 insulates the ceiling 104 from the grounded side wall 102. The sputter target 140 is typically a material, such as a metal, to be deposited on the surface of the wafer 110. A high voltage D.C. power source 142 may be coupled to the target 140 to promote plasma sputtering. RF plasma source power may be applied to the target 140 from an RF plasma source power generator 144 of frequency fs through an impedance match 146. A capacitor 143 isolates the RF impedance match 146 from the D.C. power source 142. The target 140 functions as an electrode that capacitively couples RF source power to plasma in the chamber 100.

A first (or “target”) multi-frequency impedance controller 150 is connected between the target 140 and RF ground. Optionally, a second (or “bias”) multi-frequency impedance controller 170 is connected between the output of the bias match 122 (i.e., to either the conductive base 114 or to the grid electrode 116, depending upon which one is driven by the bias generator 120). A process controller 101 controls the two impedance controllers 150, 170. The process controller can respond to user instructions to increase or decrease the impedance to ground of a selected frequency through either of the first and second multi-frequency impedance controllers 150, 170.

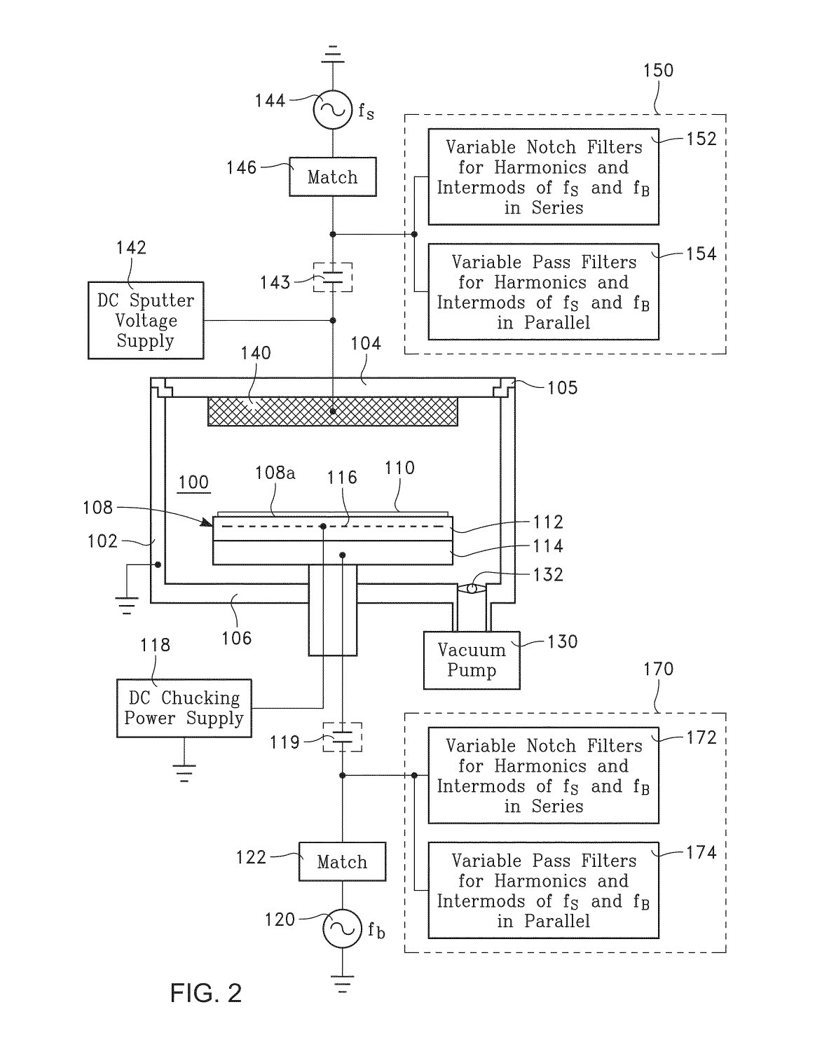

Referring to FIG. 2, the first multi-frequency impedance controller 150 includes an array 152 of variable band reject (“notch”) filters and an array 154 of variable band pass (“pass”) filters. The notch filter array 152 consists of many notch filters, each notch filter blocking a narrow frequency band, one notch filter being provided for each frequency of interest. The impedance presented by each notch filter may be variable, to provide full control of impedances for each frequency of interest. The frequencies of interest include the bias frequency f_{b}, the source frequency fₛ, harmonics of fₛ, harmonics of f_{b}, intermodulation products of fₛ and f_{b} and the harmonics of the intermodulation products. The pass filter array 154 consists of many pass filters, each pass filter passing (presenting a low impedance to) a narrow frequency band, one pass filter being provided for each frequency of interest. The impedance presented by each notch filter may be variable, to provide full control of impedances for each frequency of interest. The frequencies of interest include the bias frequency f_{b}, the source frequency fₛ, harmonics of fₛ, harmonics of f_{b}, intermodulation products of fₛ and f_{b} and harmonics of the intermodulation products.

Referring still to FIG. 2, the second multi-frequency impedance controller 170 includes an array 172 of variable band reject (“notch”) filters and an array 174 of variable band pass (“pass”) filters. The notch filter array 172 consists of many notch filters, each notch filter blocking a narrow frequency band, one notch filter being provided for each frequency of interest. The impedance presented by each notch filter may be variable, to provide full control of impedances for each frequency of interest. The frequencies of interest include the bias frequency f_{b}, the source frequency fₛ, harmonics of fₛ and f_{b} and intermodulation products of fₛ and f_{b}. The pass filter array 174 consists of many pass filters, each pass filter passing (presenting a low impedance to) a narrow frequency band, one pass filter being provided for each frequency of interest. The impedance presented by each notch filter may be variable, to provide full control of impedances for each frequency of interest. The frequencies of interest include the bias frequency f_{b}, the source frequency fₛ, harmonics of fₛ and f_{b} and intermodulation products of fₛ and f_{b}.

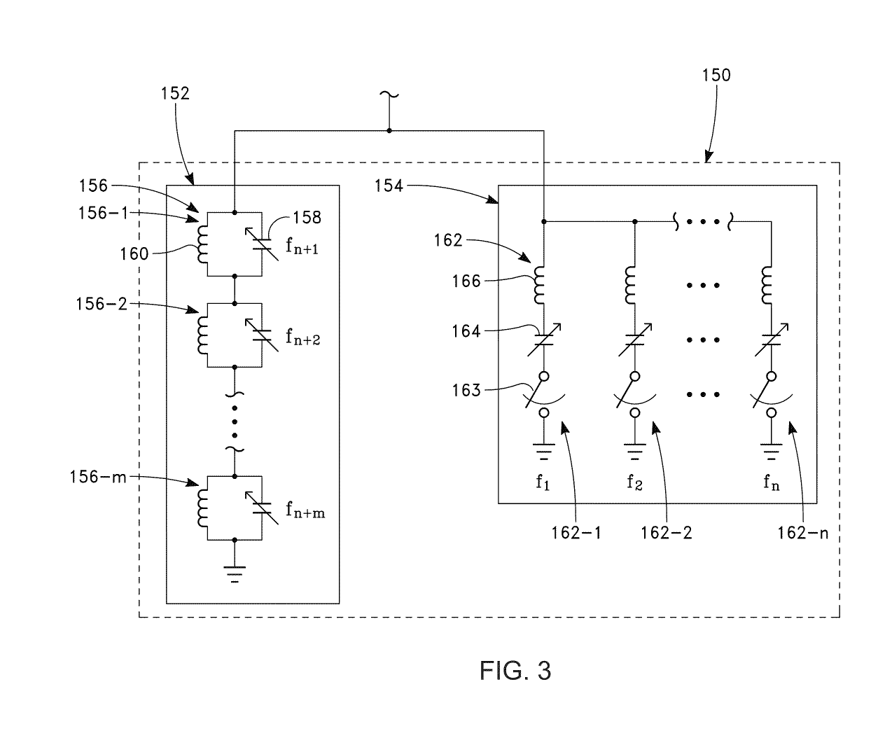

FIG. 3 depicts the target multi-frequency controller with one implementation of the notch filter array 152 and the pass filter array 154. The notch filter array 152 includes a set of m (where m is an integer) individual notch filters 156-1 through 156-m connected in series. Each individual notch filter 156 consists of a variable capacitor 158 of capacitance C and an inductor 160 of inductance L, the individual notch filter having a resonant frequency fr=1/[2π(LC)½]. The reactances L and C of each notch filter 156 are different and are selected so that the resonant frequency fr of a particular notch filter corresponds to one of the frequencies of interest, each notch filter 156 having a different resonant frequency. The resonant frequency of each notch filter 156 is the center of the narrow band of frequencies blocked by the notch filter 156. The pass filter array 154 of FIG. 3 includes a set of n (where n is an integer) individual pass filters 162-1 through 162-n connected in parallel. Each individual pass filter 162 consists of a variable capacitor 164 of capacitance C and an inductor 166 of inductance L, the pass filter 162 having a resonant frequency fr=1/[2π(LC)½]. Optionally, each pass filter 162 may include, in addition, a series switch 163 to permit the pass filter to be disabled whenever desired. The reactances L and C of each pass filter 162 are different and are selected so that the resonant frequency fr corresponds to one of the frequencies of interest, each pass filter 162 having a different resonant frequency. The resonant frequency of each pass filter 162 is the center of the narrow band of frequencies passed or admitted by the pass filter 162. In the implementation of FIG. 3, there are n pass filters 162 in the pass filter array 154 and m notch filters in the notch filter array 152.

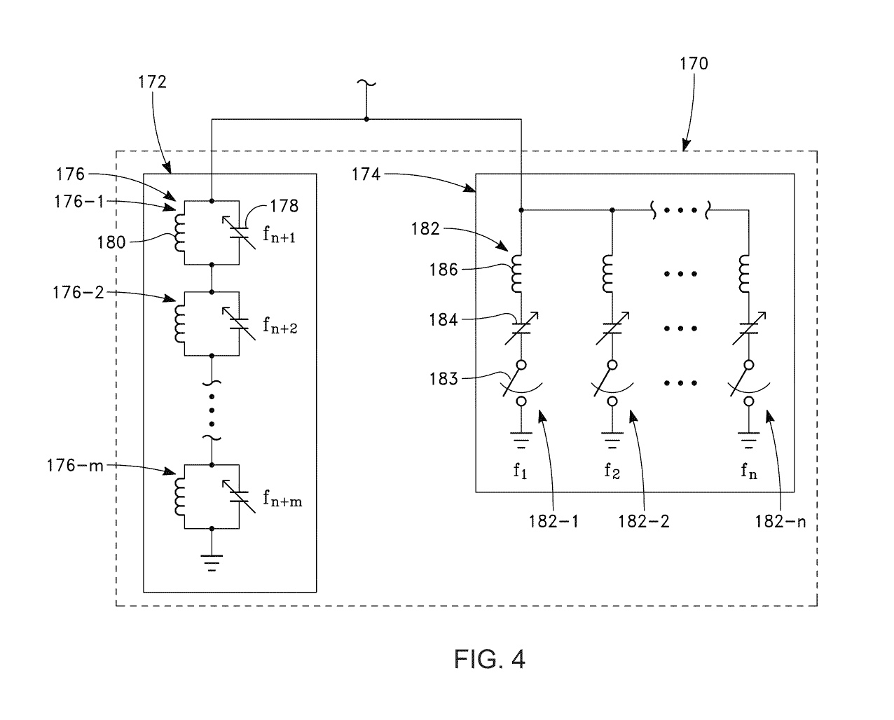

The notch filter array 172 and pass filter array 174 for the second multi-frequency impedance controller 170 may be implemented in a similar manner, as depicted in FIG. 4. The notch filter array 172 includes a set of m (where m is an integer) individual notch filters 176-1 through 176-m connected in series. Each individual notch filter 176 consists of a variable capacitor 178 of capacitance C and an inductor 180 of inductance L, the individual notch filter having a resonant frequency fr=1/[2π(LC)½]. The reactances L and C of each notch filter 176 are different and are selected so that the resonant frequency fr of a particular notch filter corresponds to one of the frequencies of interest, each notch filter 176 having a different resonant frequency. The resonant frequency of each notch filter 176 is the center of the narrow band of frequencies blocked by the notch filter 176.

The pass filter array 174 of FIG. 4 includes a set of n (where n is an integer) individual pass filters 182-1 through 182-n connected in parallel. Each individual pass filter 182 consists of a variable capacitor 184 of capacitance C and an inductor 186 of inductance L, the pass filter 182 having a resonant frequency fᵣ=1/[2π(LC)½]. Optionally, each pass filter 182 may include, in addition, a series switch 183 to permit the pass filter to be disabled whenever desired. The reactances L and C of each pass filter 182 are different and are selected so that the resonant frequency fᵣ corresponds to one of the frequencies of interest, each pass filter 182 having a different resonant frequency. The resonant frequency of each pass filter 182 is the center of the narrow band of frequencies passed or admitted by the pass filter 182. In the implementation of FIG. 4, there are n pass filters 182 in the pass filter array 174 and m notch filters 176 in the notch filter array 172.

Precise control of RF ground return paths through each of the multi-frequency impedance controllers at selected frequencies is attained by the process controller 101 individually governing each of the variable capacitors 158, 164 of the first multi-frequency impedance controller 150 and each of the variable capacitors 178, 184 of the second multi-frequency impedance controller 170.

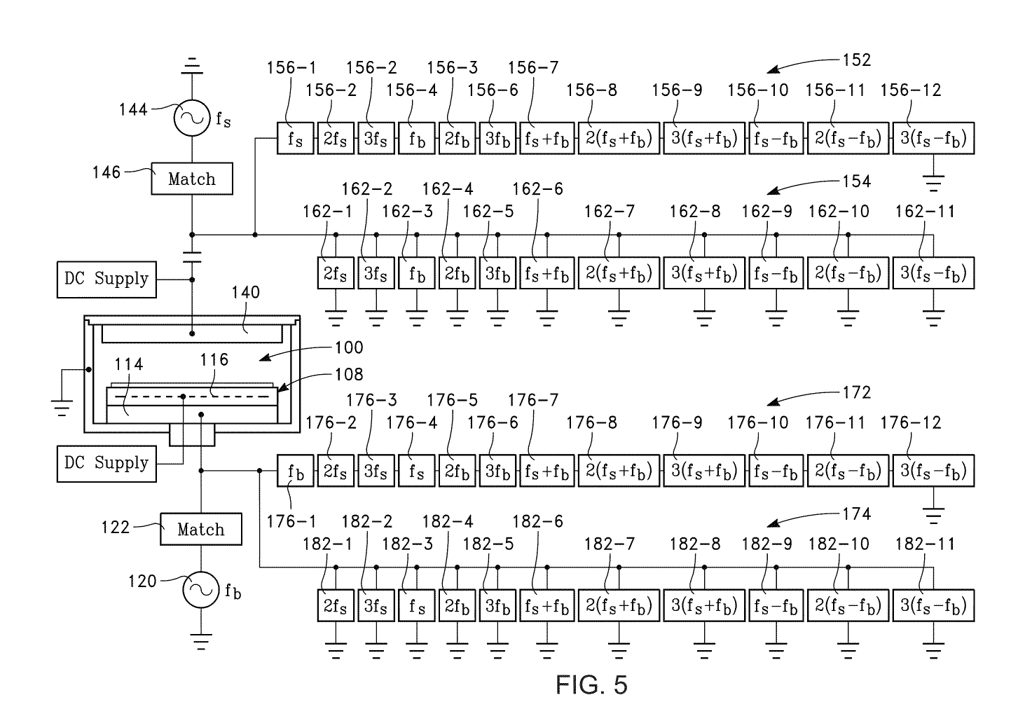

Referring now to FIG. 5, the resonant frequencies of the n pass filters 162-1 through 162-11 in the pass filter array 154 of the first (target) multi-frequency impedance controller 150 are harmonics and intermodulation products of the source and bias power frequencies fs and fb may include the following frequencies: 2fₛ, 3fₛ, f_{b}, 2f_{b}, 3f_{b}, fₛ+f_{b}, 2(fₛ+f_{b}), 3(fₛ+f_{b}), fₛ−f_{b}, 2(fₛ−f_{b}), 3(fₛ−f_{b}).

In this example, n=11. The resonant frequencies of the m notch filters 156-1 through 156-12 in the notch filter array 152 of the first multi-frequency impedance controller are also harmonics and intermodulation products of the source and bias power frequencies fs and fb may include the following frequencies: fₛ, 2fₛ, 3fₛ, f_{b}, 2f_{b}, 3f_{b}, fₛ+f_{b}, 2(fₛ+f_{b}), 3(fₛ+f_{b}), fₛ−f_{b}, 2(fₛ−f_{b}), 3(fₛ−f_{b}). In this example, m=12. The notch filter 156-1 having the resonant frequency fs blocks the fundamental frequency of the source power generator 144 to prevent it from being shorted through the impedance controller 150.

Referring still to FIG. 5, the resonant frequencies of the n pass filters 182-1 through 182-11 in the pass filter array 174 of the second (bias) multi-frequency impedance controller 170 are harmonics and intermodulation products of the source and bias power frequencies fₛ and f_{b} may include the following frequencies: 2fs, 3fₛ, fₛ, 2f_{b}, 3f_{b}, fₛ+f_{b}, 2(fₛ+f_{b}), 3(fₛ+f_{b}), fₛ−f_{b}, 2(fₛ−f_{b}), 3(fₛ−f_{b}), in which case n=11. The resonant frequencies of the m notch filters 176-1 through 176-12 in the notch filter array 172 of the second (bias) multi-frequency impedance controller 170 are also harmonics and intermodulation products of the source and bias power frequencies fs and fb may include the following frequencies: f_{b}, 2fₛ, 3fₛ, fₛ, 2f_{b}, 3f_{b}, fₛ+f_{b}, 2(fₛ+f_{b}), 3(fₛ+f_{b}), fₛ−f_{b}, 2(fₛ−f_{b}), 3(fₛ−f_{b}). In this example, m=12. The notch filter 176-1 having the resonant frequency f_{b} blocks the fundamental frequency of the bias power generator 120 to prevent it from being shorted through the impedance controller 170.

As described above, each pass filter (162, 182) may include an optional switch (163, 183, respectively) to disable the pass filter in the event that its resonant frequency is to be blocked by a notch filter. For example, each pass filter 162 of FIG. 3 can include a series switch 163, and each pass filter 182 of FIG. 4 can include a series switch 183. However, if the multi-frequency impedance controllers 150, 170 are implemented with prior knowledge of which frequencies are to be blocked and which ones are to be admitted through the respective controllers, then, within a particular controller, a notch filter would be provided for each frequency to be blocked by that controller, and no pass filter would be provided in that controller for the blocked frequencies. In such an implementation, the notch filters would be tuned only to the frequencies to be blocked while the pass filters would be tuned only to the frequencies to be admitted within an individual controller, the two sets of frequencies being mutually exclusive in one embodiment. This implementation would avoid the need for the pass filter series switches 163, 183.

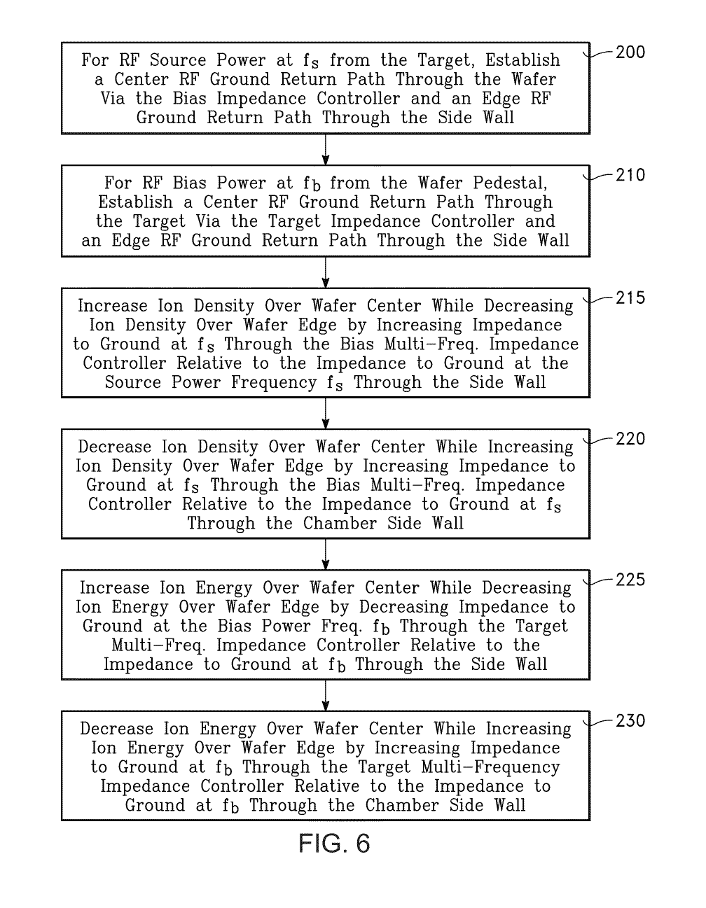

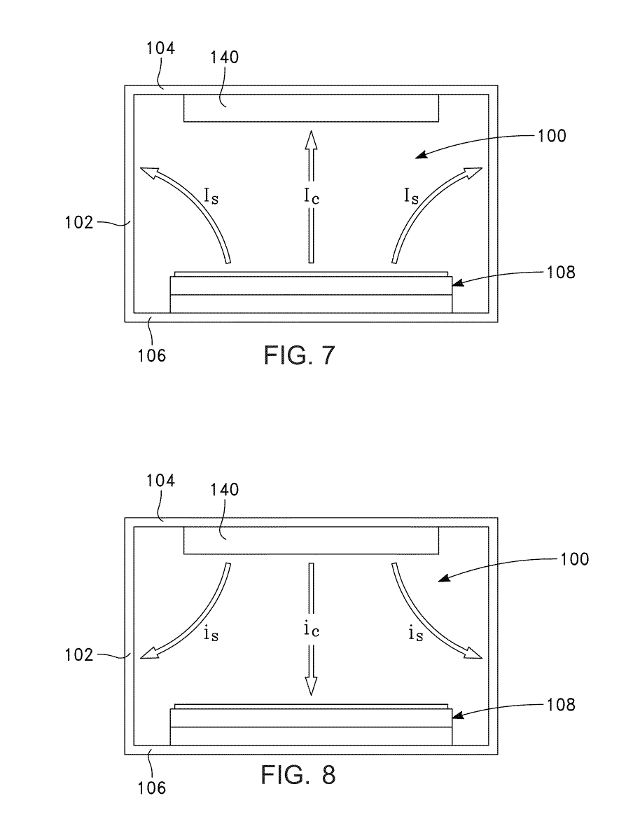

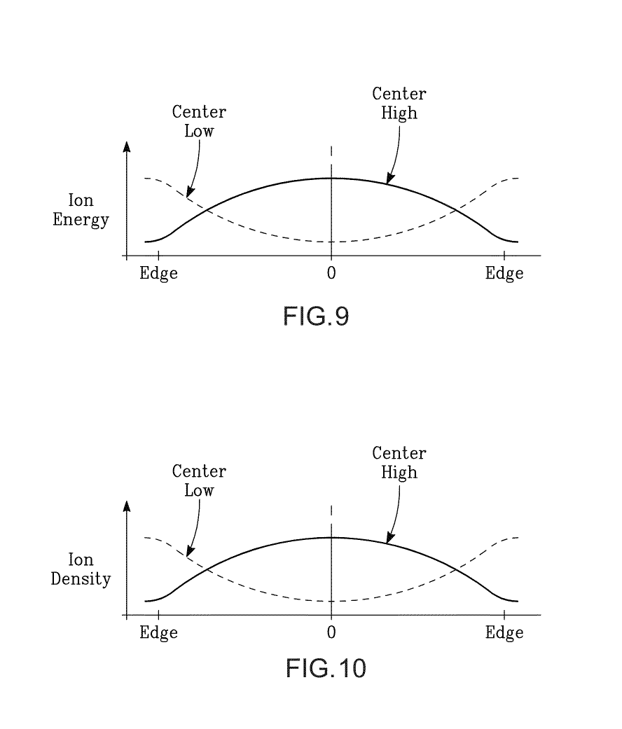

FIG. 6 depicts a method of operating the reactor of FIGS. 1 through 3. In the method, the bias power current from the wafer is apportioned, as depicted in FIG. 7, between a center path to the target, Ic, and an edge path Is, to the side wall. Also, source power current from the target is apportioned, as depicted in FIG. 8, between a center path to the wafer, i_{c}, and an edge path is, to the side wall. Thus, for RF source power at the source power frequency fs from the target, the method includes establishing a center RF ground return path through the wafer via the bias impedance controller 170 and an edge RF ground return path through the side wall (block 200 of FIG. 6). For RF bias power at f_{b} from the wafer pedestal, the method includes establishing a center RF ground return path through the target via the target impedance controller 150 and an edge RF ground return path through the side wall (block 210 of FIG. 6).

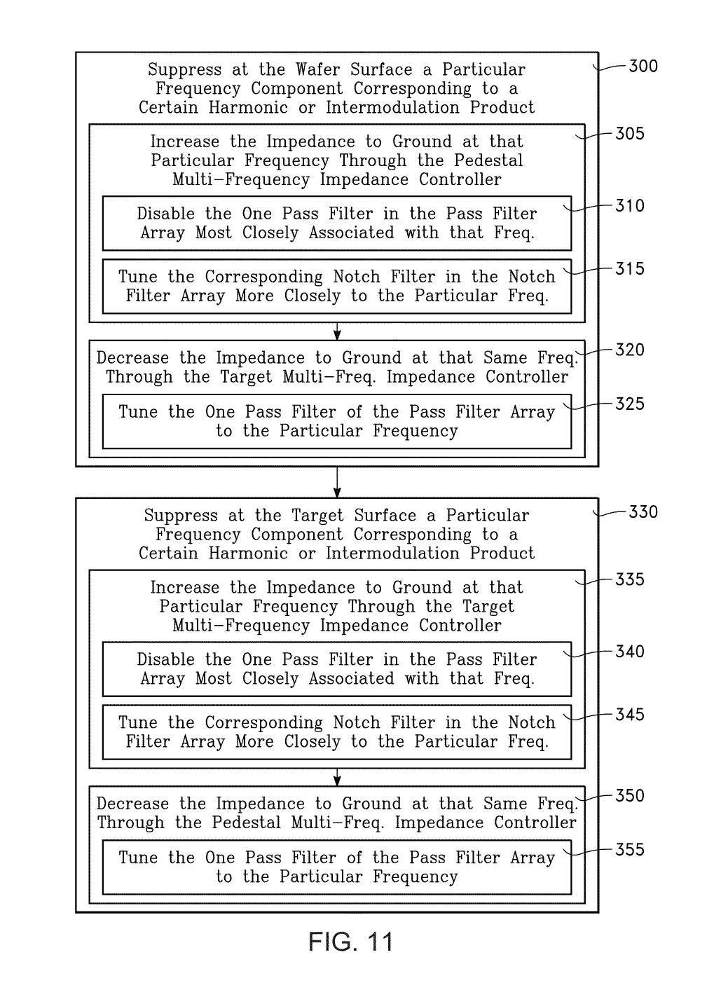

In one aspect of the method, ion density over wafer center is increased while decreasing ion density over wafer edge, by decreasing impedance to ground at fs through the bias multi-frequency impedance controller 170 relative to the impedance to ground at the source power frequency fₛ through the side wall (block 215 of FIG. 6). This increases the tendency toward a center high ion density distribution depicted in solid line in FIG. 9. This step may be carried out by adjusting the resonant frequency of the pass filter 182-3 closer to the source frequency fs.

In another aspect, ion density is decreased over wafer center while increasing ion density over wafer edge by increasing impedance to ground at fs through the bias multi-frequency impedance controller 170 relative to the impedance to ground at fs through the side wall (block 220 of FIG. 6). This increases the tendency toward a center low edge high ion density distribution depicted in dashed line in FIG. 9. This step may be carried out by adjusting the resonant frequency of the pass filter 182-3 further (away) from the source frequency fs.

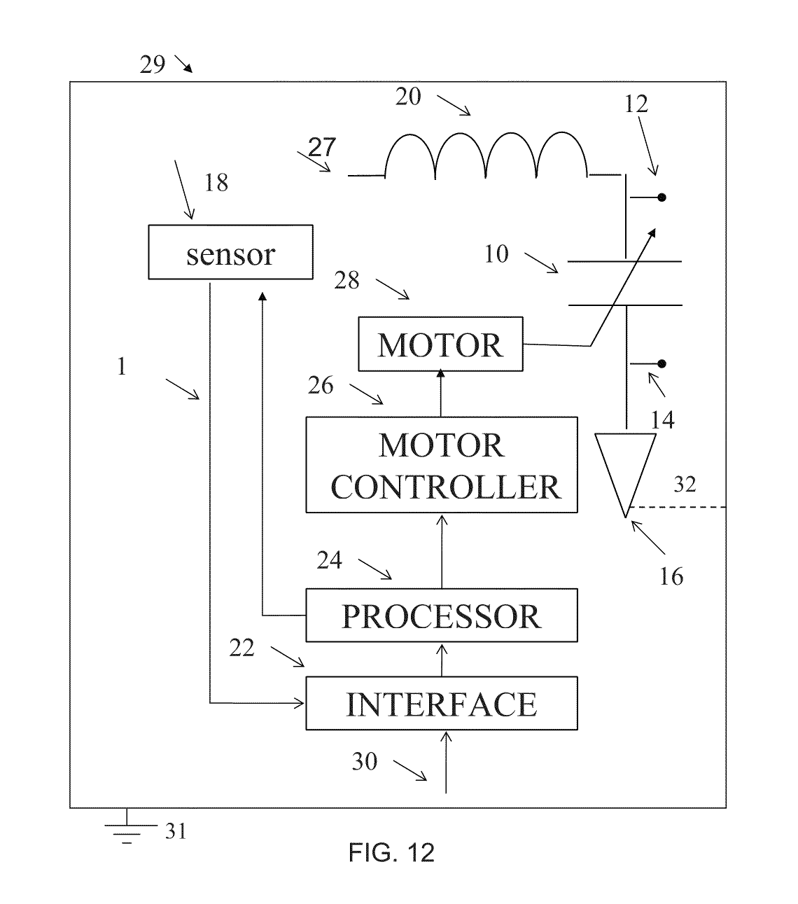

In a further aspect, ion energy over wafer center is increased while decreasing ion energy over wafer edge by decreasing impedance to ground at the bias power frequency f_{b} through the target multi-frequency impedance controller 150 relative to the impedance to ground at f_{b} through the side wall (block 225 of FIG. 6). This increases the tendency toward a center high ion energy distribution depicted in solid line in FIG. 10. This step may be carried out by adjusting the resonant frequency of the pass filter 162-3 closer to the bias frequency f_{b}.

In a yet further aspect, ion energy over wafer center is decreased while increasing ion energy over wafer edge by increasing impedance to ground at f_{b} through the target multi-frequency impedance controller 150 relative to the impedance to ground at fb through the side wall (block 230 of FIG. 6). This increases the tendency toward a center low edge high ion energy distribution depicted in dashed line in FIG. 10. This step may be carried out by adjusting the resonant frequency of the pass filter 162-3 further away from the bias frequency f_{b}.

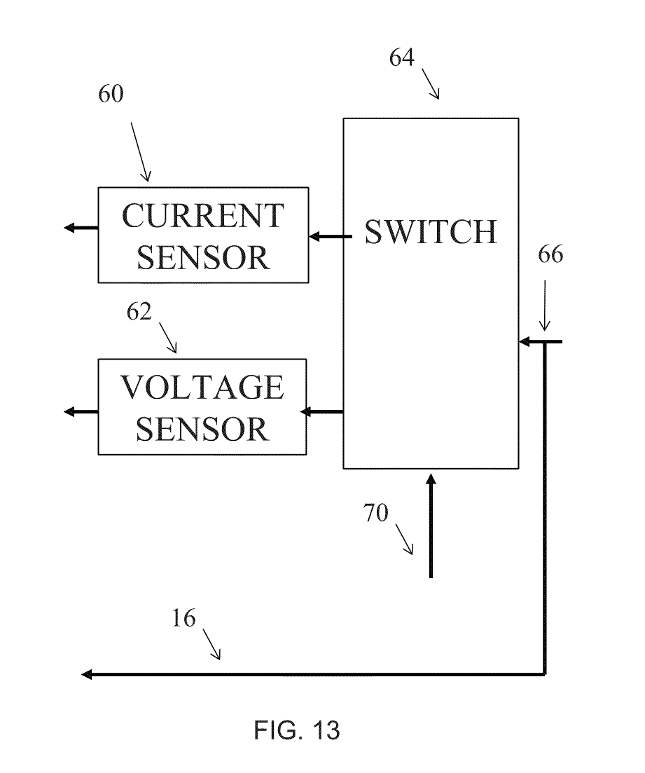

FIG. 11 illustrates a method for suppressing harmonics and/or intermodulation products or their harmonics at a chosen one of either the wafer surface or the target surface. Different frequencies may be suppressed at the different surfaces. This may be carried out, in one application, to optimize chamber matching among reactors of identical design, for example. In order to suppress at the wafer surface a particular frequency component corresponding to a certain harmonic or intermodulation product (block 300 of FIG. 11), plasma current components at that frequency are diverted to a surface other than the wafer surface, such as the side wall or the ceiling or target. In order to divert the undesired frequency component from the wafer to the ceiling, the impedance to ground at that particular frequency through the pedestal multi-frequency impedance controller 170 is increased (block 305 of FIG. 11). This may be accomplished by de-tuning or disabling the one pass filter in the pass filter array 174 most closely associated with that frequency (block 310), if there is one. In addition, the corresponding notch filter in the notch filter array 172 may be tuned more closely to the particular frequency (block 315). Optionally, or in addition, the undesired frequency component is drawn away from the wafer surface by diverting it to the target 140. This may be accomplished by decreasing the impedance to ground at the particular frequency through the target multi-frequency impedance controller 150, to divert the undesired components to ground through the target 140 and away from the wafer (block 320). This latter step may be accomplished by tuning one of the pass filters 156 having a corresponding resonant frequency closer to the frequency of the undesired component (block 325).

In order to suppress at the target surface a particular frequency component corresponding to a certain harmonic or intermodulation product (block 330), the impedance to ground at that particular frequency through the target multi-frequency impedance controller 150 is increased (block 335). This may be accomplished by de-tuning (or disconnecting) the one pass filter in the pass filter array 154 most closely associated with that frequency (block 340). In addition the corresponding notch filter in the notch filter array 152 may be tuned more closely to the particular frequency (block 345). Optionally, and in addition, the impedance to ground at that same frequency through the pedestal multi-frequency impedance controller 170 is decreased, to divert those components to ground away from the target (block 350). This latter step may be accomplished by tuning the one pass filter of the pass filter array 174 to the particular frequency (block 355).

Some of the foregoing steps may be employed to promote a desired frequency component at either the wafer surface or at the target surface. The plasma current frequency component may be chosen to be one which promotes or increases a particular action of the plasma, such as sputtering or deposition or etching. For example, a chosen plasma current frequency component may be directed or diverted to the target for such a purpose. This direction or diversion may be accomplished by performing the step of block 325, in which a chosen plasma current frequency component is diverted to the target 140. The diversion may be more complete by additionally performing the step of block 315 to repulse the chosen frequency component from the wafer surface.

Another chosen plasma current frequency component may be diverted to the wafer surface for a similar or other purpose (increase etch rate, deposition rate or sputter rate at the wafer surface, for example). This diversion may be accomplished by performing the step of block 355, in which a chosen plasma current frequency component is diverted to the wafer surface. This diversion may more complete by additionally performing the step of block 345 to repulse the chosen frequency component from the target surface. As one example, the chosen frequency component may be a frequency (a fundamental or harmonic or intermodulation product) that promotes a particular plasma action, such as sputtering. If it is desired to sputter the wafer without sputtering the target, then that frequency component is diverted away from the target and to the wafer by raising the impedance at that frequency through the target impedance controller 150 while reducing the impedance at the same frequency through the bias impedance controller 170. Conversely, if it is desired to sputter the target without sputtering the wafer, then that frequency component is diverted away from the wafer and to the target by decreasing the impedance at that frequency through the target impedance controller 150 while increasing the impedance at the same frequency through the bias impedance controller 170. The desired plasma effect may be obtained with a particular set of plural frequency components. In such a case, the plural frequency components are controlled in the foregoing manner using plural notch and/or pass filters operated simultaneously in accordance with the foregoing.

The foregoing features may be implemented in a plasma reactor lacking a sputter target, e.g., a plasma reactor adapted for processes other than physical vapor deposition. In such a reactor, for example, the target 140 and DC source 142 of FIG. 1 are absent, and the RF source power generator 144 and match 146 may be coupled to the ceiling 104. The ceiling 104 in such a case functions as a plasma source power applicator in the form of an electrode for capacitively coupling plasma source power into the chamber 100. In an alternative embodiment, the source power generator 144 and match 146 may be coupled to another RF source power applicator at the ceiling, such as a coil antenna for example.

In a further embodiment of the present invention tuning of the capacitive or inductive coupling of the substrate on the pedestal to the target is achieved by applying a variable capacitor that is put in a setting by a motor such as a stepping motor. It adjusts the substrate impedance, thereby adjusting the amount of bias that builds up on the substrate.

It has been shown above that the impedance of impedance controller 170 can be adjusted by variable capacitors 178 and/or 184 in impedance controller 170. It is desirable that reaction chambers of a specific common design for processing similar products or substrates can be put in an identical or close to identical operating condition. This can be achieved by having an operator or a processor or a combination of both provide a controller with identical or close to identical settings. These settings may include operational settings for a power source and the like. A common impedance setting in an impedance controller in one embodiment of a processing chamber is a common setting to achieve identical or close to identical operating conditions for at least two processing chambers. The impedance setting in a further embodiment relates to an impedance setting of a variable impedance between the pedestal and ground. In yet a further embodiment the impedance is made variable by a variable capacitor which can be operated to have one of several or a range of electronic capacitance.

Such variable capacitors are known, and may be obtained for instance from Comet North America's Office in San Jose, Calif.

Even if processing chambers are of the same designs there may be chamber to chamber variations, wherein individual parameter settings may vary to achieve identical or close to identical processing outcomes. A chamber may be provided with a specific (common) recipe for a desired outcome. A controller of the chamber may adjust at least one parameter in a standard recipe to adjust the required setting for a known variation to achieve the desired outcome.

In one embodiment the setting of the variable capacitor in a chamber may be determined to have a variation compared to a standard recipe to achieve a desired impedance adjustment for optimal ion energy or density distribution related to a desired processing outcome. In a further embodiment, the desired capacitance or capacitance setting may be programmed in a controller of the chamber. The variable capacitor can be set in a specific position for a desired capacitance. Based on a desired set-point a processor may control a motor, such as a stepper motor, to put the variable capacitor in a desired setting. A desired setpoint of the variable capacitor may be determined by a value of a voltage or a current at that setpoint. The processor is programmed to change the capacitance of the capacitor until the value of the voltage or current is achieved. The variable capacitor in that case is associated with a voltage or a current sensor that provides feedback to the processor and continues to adjust the capacitance of the variable capacitor until the desired value of the sensed voltage or current is achieved.

The above allows the setting of the variable capacitor for a desired common outcome for instance related to a specific recipe to be adjusted for chamber-to-chamber variation, while still achieving a desired outcome. It also allows a chamber to be provided with a menu driven automatic controller, wherein similar chambers are programmed and controlled to process and deliver identical or close to identical products, without having to manually adjust parameter settings when a certain menu option is selected. In one embodiment, one may have to go through a calibration step to determine to what extent a setting such as a variable capacitor setting has to be adjusted to achieve a predetermined outcome. Once, the calibration has taken place, one may program a process controller to put the variable capacitor in a required position. In a further embodiment, a position of the variable capacitor may be associated with a current or voltage as applied to achieve an optimal setting. A sensor collaborates with a processor to put the variable capacitor in a position that corresponds with the desired voltage or current value.

The above then achieves a tuning of an impedance of the chamber based on a desired and predefined outcome, taking into account chamber-to-chamber variation.

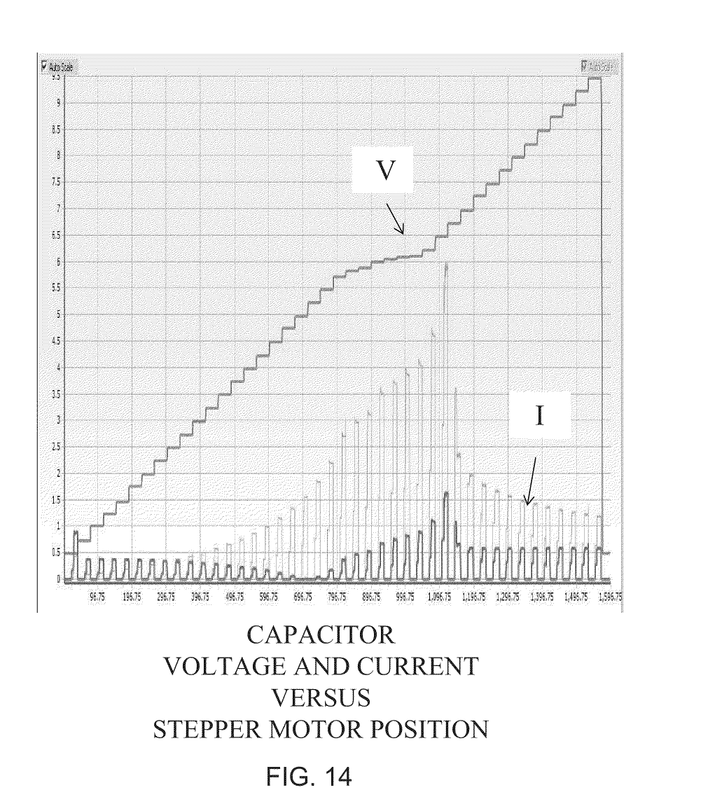

We will now turn to FIG. 12 to explain one or more aspects of the present invention that use a variable capacitor.

FIG. 12 illustrates a variable capacitor tuning circuit with a feedback circuit in accordance with one aspect of the present invention. This circuitry can be used in a variety of RF physical vapor deposition type chambers. For example, the variable capacitor 10 can be used in box 170 in FIGS. 1, 2 and 4. Thus, it is understood that other components may be included, as is known, to improve processing. However, in accordance with one aspect of the present invention, a motor controlled variable capacitor 10 is included, as shown in FIG. 12.

The circuit allows the deposition of a metal or non-metal layer on a wafer/substrate. As will be discussed below, the variable capacitive tuning circuit can be automated for a given set point. The set point can be current, voltage or a percentage of the full scale of the capacitance of the variable capacitor. The set point can depend on the desired processing.

Referring to FIG. 12, the adaptive tuner capacitor circuit 1 of the present invention can include a variable capacitor 10, an output 16 which may be connected to ground, an optional sensor circuit 18, an optional inductor 20. an interface 22, a processor 24, a motor controller 26 and a motor 28. The circuit has a connection point 27 to connect to the pedestal. The inductor 20, which is optional, may be a variable inductor. The motor 28 is preferably a stepper motor that is attached to the variable capacitor 10 in a manner to be able to vary the capacitance of the variable capacitor 10. The sensor 18 may for instance be placed in the circuit to sense a current through the capacitor.

A current through the variable capacitor 10 may be provided through an inductor 20 and may go through the sensor 18. The inductor 20 is optional. It may be provided to create a tuner circuit of the present invention with a certain band-pass characteristic. The sensor 18 is also optional and, if used, can be placed at points 27, 12 or 14 in the circuit.

The variable capacitor may be placed in a housing 29. The housing may be grounded via optional ground connection 31. The output 16 of the variable capacitor 10 may be connected through a connection 32 to the housing 29 and thus 16 has then the same potential as the housing. When the housing is grounded and connection 32 exists, then 16 also has the potential of ground.

In accordance with various aspects of the present invention, it is contemplated that other components can be provided in the circuit 1 of FIG. 12. The sensor circuit 18 is optional, and can include a sensor to determine the output of the variable capacitor 10. The sensors can be a voltage sensor or a current sensor. These sensors will be used to provide feedback to control a motor and to control the operational set point of the variable capacitor 10, as will be discussed.

The sensor circuit 18, if included, provides a feedback signal to the interface 22. The interface 22 provides the feedback signal to the processor 24. The processor 24 can be a dedicated electric circuit or it can also be a microprocessor or microcontroller based circuit. The interface 22 is optional. The interface 22 may provide a manual interface to set a position of the variable capacitor. The interface 22 may also provide a signal that reflects a capacitance setting of the variable capacitor. The interface 22 may be connected to the motor to provide a movable scale that provides a visual indication of the actual setting of the variable capacitor.

The processor 24 controls the motor controller 26 which controls the motor 28 in accordance with the mode control signal and the outputs of the sensors. The motor controller 26 causes the motor 28, which is preferably a stepper motor, to step through its positions to vary the capacitance of the variable capacitor 10 as a function of the mode control signal and of the outputs of the sensors. Accordingly, the variable capacitor can be put in a range of capacitance values, at least in a first capacitance and a second capacitance, which are different capacitances. Each capacitance of the variable capacitor in a range of capacitances corresponds to a state of the variable capacitor. A state of the variable capacitor corresponds with an impedance value at a certain frequency. In one embodiment, a variable capacitor is put in a first state to achieve an impedance at a first frequency.

A state of a variable capacitor 10 in one embodiment may be defined as a position of the interface 22, or as a position of the motor 28 or as a measured current or voltage by the sensor 18, or in any other phenomenon that defines a state of the variable capacitor. A state of the variable capacitor in a further embodiment is encoded in a process controller for a recipe of a desired outcome of a process run of the chamber. The state of the variable capacitor preferably being adjusted for chamber-to-chamber variations related to the desired outcome. Accordingly, when a process controller is initiated to run a pre-defined process in a chamber, a desired state of the variable capacitor is retrieved from a memory, that stores for instance a process recipe, and instructs the processor 24 to put variable capacitor 10 through for instance motor controller 26 to motor controller 28 in the desired position. It is to be understood that a desired position may depend on a variable factor such as a current or a voltage. During the chamber process the current may change. The processor 24 may enable the variable capacitor to follow variations in a current or a voltage during the process or to adjust to variations in a current or a voltage according to predefined control instructions.

In a further embodiment a state of the variable capacitor is related to a stage of a process in the chamber. A process controller may provide an instruction to change the state of the variable capacitor to a new state based on for instance a stage of the process.

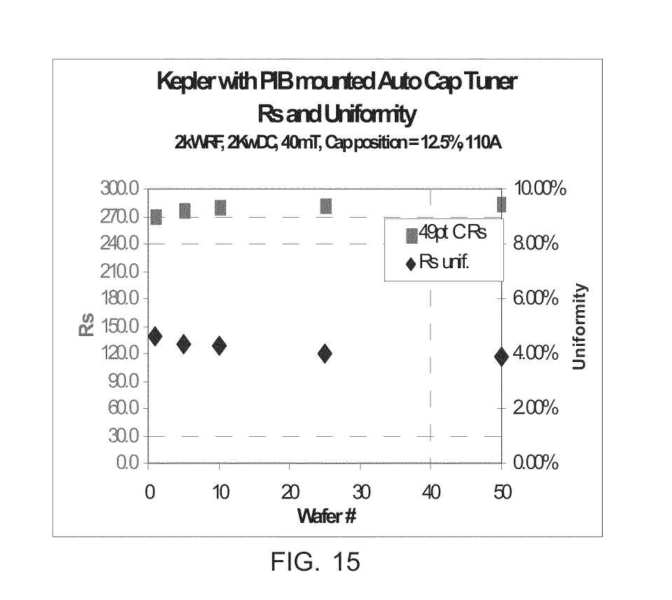

FIG. 13 illustrates an embodiment of the sensor circuit 18 in accordance with an aspect of the present invention. In this embodiment, the sensor circuit 18 includes a current sensor 60, a voltage sensor 62 and a switch 64. The switch 64 receives an input either directly or indirectly from the variable capacitor 10. The input to the switch 64 is also provided on the output 16.

The switch 64 selectively provides the power it receives on its input on one of its outputs, depending on the value of the signal on a control input 70. As illustrated in FIG. 12, the control input 70 is provided by the processor 24 in accordance with the mode control input signal.

The processor 24 decides what set point is desired and how to control the switch 64 based on an input on line 30 in FIG. 12. The set point can either be a voltage if a constant voltage is desired. When the mode control input specifies a voltage control mode, the processor 24 the switch 64 to connect the voltage sensor 60 to the output of the variable capacitor 10 and the processor 24 controls the motor controller 26 based on the output of the voltage sensor 60 to maintain a constant voltage on the output of the variable capacitor 10.

When the mode control input signal specifies a current control mode, the processor 24 causes the switch 64 to connect the current sensor 62 to the output of the variable capacitor 10 and controls the motor controller 26 based on the output of the current sensor 62 to maintain a constant current on the output of the variable capacitor 10.

When the mode control input signal specifies a setpoint mode, the processor 24 controls the motor controller based on a set point specified by the mode control input signal to cause the motor to vary the capacitance of the variable capacitor in accordance with the specified set point.

The processor 24 can also be a special purpose interface circuit. The main purpose of the interface circuit or processor 24 is to control the motor controller as a function of the mode control input, the voltage sensor output and the current sensor output, as just described. If the mode control input specifies a set point, then the motor controller 26 is controlled to generate the capacitance specified by the input. If the mode control input specifies a voltage mode, then the motor controller 26 controls the motor 28 in accordance with the output of the voltage sensor 62 to maintain a constant voltage at the capacitor 10. If the mode control input specifies a current mode, then the motor controller 26 controls the motor 28 to maintain a constant current at the capacitor 10.

As previously mentioned, the control circuit of FIG. 13 is optional. If only a selectable set point is desired, then the processor 24 can receive that desired set point and control the motor 28 through the motor controller 26 to reach that desired set point. This set point can be selected based on the processing desired. If a constant voltage set point is desired, then the voltage sensor can also be supplied. If a constant current set point is desired, then the current sensor can be supplied.

Any type of well known voltage sensor can be used in accordance with the various aspects of the present invention. Similarly, any type of well know current sensor can be used in accordance with the various aspects of the present invention. Both voltage sensors and current sensors are well known in the art.

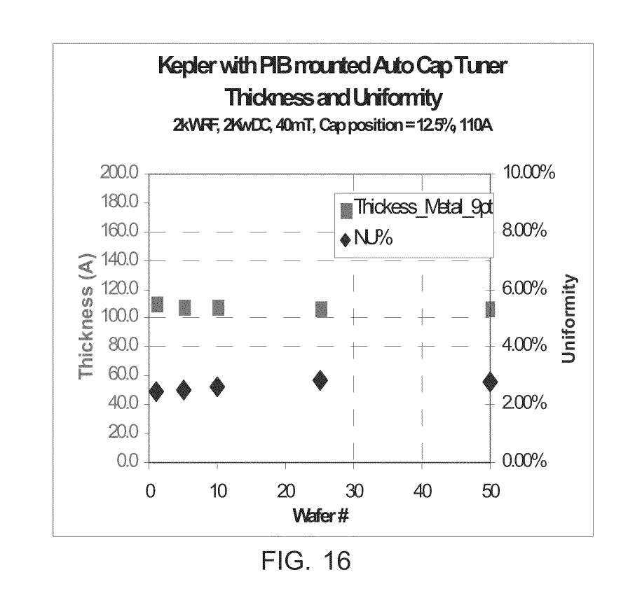

FIG. 14 illustrates the variable capacitor 10 voltage output V and current output I as the motor 28 is stepped through its various positions by the motor controller 26. As can be seen, the variable capacitor 10 is adequately and accurately controlled by the motor 28 and the motor controller 26 in accordance with the various aspects of the present invention.

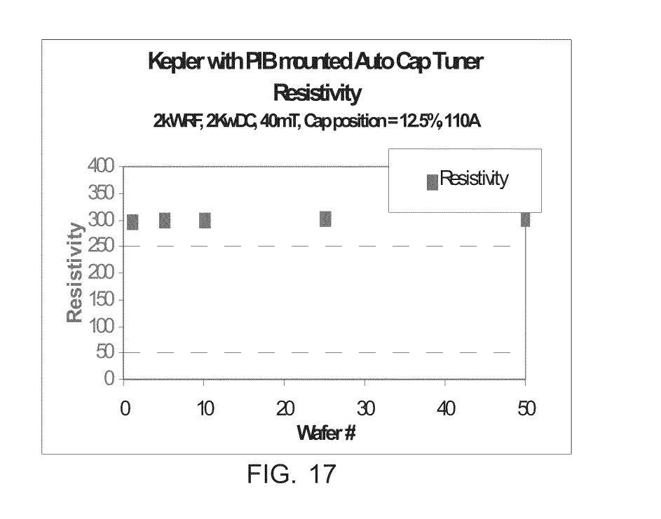

FIGS. 15 to 17 illustrate processing results across fifty (50) wafers using the variable capacitive tuner with feedback in accordance with various aspects of the present invention in a physical vapor deposition process. Rₛ is sheet resistance. It is a well known term in the art. It is a resistance normalized to an area, so that it only depends on material resistivity and thickness. FIG. 15 illustrates Rₛ over the fifty wafers. This illustrates acceptable variations in Rₛ using the variable capacitive tuner of the present invention.

FIG. 16 illustrates thickness variations obtained over fifty wafers using the variable capacitive tuner circuit of the present invention in a physical vapor deposition process. Once again, FIG. 16 illustrates acceptable variations in wafer thickness using the variable tuner circuit of the present invention.

FIG. 17 illustrates resistivity variations obtained over fifty wafers using the variable capacitive tuner circuit of the present invention in a physical deposition process. Once again, FIG. 16 illustrates acceptable variations in wafer resistivity using the variable tuner circuit of the present invention.

A novel method of providing plasma processing such as physical vapor deposition or etching on a wafer supported on a pedestal is also provided. The method includes supporting a wafer on the pedestal, and supplying power to the pedestal in a frequency range based on the capacitance of the variable capacitor.

An input signal specifies an operational set point to a circuit that specifies the capacitance for the variable capacitor. The method can also include sensing a voltage or a current with a sensor and feeding the output of the sensor to a feedback circuit that controls the motor controller to place the variable capacitor in a desired position.

As shown above, the sensor can be a voltage sensor and the feedback circuit monitors the voltage at the output of the variable capacitor and controls the motor controller to maintain the voltage at the output of the variable capacitor as a constant value. The sensor can also be a current sensor and the feedback circuit monitors the current at the output of the variable capacitor and controls the motor controller to maintain the current at the output of the variable capacitor as a constant value.

While the foregoing is directed to embodiments of the present invention, other and further embodiments of the invention may be devised without departing from the basic scope thereof, and the scope thereof is determined by the claims that follow.

What is claimed is:

1. A physical vapor deposition plasma reactor, comprising:
a chamber including a side wall and a ceiling, said side wall being coupled to an RF ground;
a workpiece support within the chamber having a support surface facing the ceiling and a bias electrode underlying the support surface;
a sputter target at said ceiling;
an RF source power supply of a first frequency coupled to said sputter target, and an RF bias power supply of a second frequency coupled to said bias electrode;
a multi-frequency impedance controller providing at least a first adjustable impedance at a first set of frequencies, said multi-frequency impedance controller comprising a variable capacitor enabled to be placed in at least one of two states by a motor, the at least two states of the variable capacitor having different capacitances.

2. The physical vapor deposition plasma reactor as claimed in claim 1, wherein the multi-frequency impedance controller further comprises an inductive element connected in series with the variable capacitor.

3. The physical vapor deposition plasma reactor as claimed in claim 1, wherein the multi-frequency impedance controller further comprises a processor to control the motor of the variable capacitor.

4. The physical vapor deposition plasma reactor as claimed in claim 3, wherein the multi-frequency impedance controller further comprises a current sensor to control the motor of the variable capacitor.

5. The physical vapor deposition plasma reactor as claimed in claim 3, wherein the multi-frequency impedance controller further comprises a voltage sensor to control the motor of the variable capacitor.

6. The physical vapor deposition plasma reactor as claimed in claim 1, wherein a state of the variable capacitor is associated with a process recipe in a process controller.

7. The physical vapor deposition plasma reactor as claimed in claim 1, further comprising a housing for the variable capacitor.

8. The physical vapor deposition plasma reactor as claimed in claim 7, wherein an output of the variable capacitor is connected to the housing.

9. The physical vapor deposition plasma reactor as claimed in claim 8, wherein the housing is connected to ground.

10. The physical vapor deposition plasma reactor as claimed in claim 6, wherein the process recipe is a common process recipe adjusted for a chamber-to-chamber variation.

11. A plasma reactor, comprising:
a chamber including a side wall and a ceiling, said side wall being coupled to an RF ground, the chamber sustaining a plasma for material deposition;
a workpiece support within the chamber having a support surface facing the ceiling and a bias electrode underlying the support surface;
a source power applicator at said ceiling;
an RF source power supply of a first frequency coupled to said source power applicator, and an RF bias power supply of a second frequency coupled to said bias electrode;
a multi-frequency impedance controller providing at least a first adjustable impedance at a first set of frequencies, said multi-frequency impedance controller comprising a variable capacitor enabled to be placed in at least one of two states by a motor, the at least two states of the variable capacitor having different capacitances.

12. The plasma chamber as claimed in claim 11, wherein the multi-frequency impedance controller further comprises an inductive element connected in series with the variable capacitor.

13. The plasma chamber as claimed in claim 11, wherein the multi-frequency impedance controller further comprises a processor to control the motor of the variable capacitor.

14. The plasma chamber as claimed in claim 13, wherein the multi-frequency impedance controller further comprises a current sensor to control the motor of the variable capacitor.

15. The plasma chamber as claimed in claim 13, wherein the multi-frequency impedance controller further comprises a voltage sensor to control the motor of the variable capacitor.

16. The plasma chamber as claimed in claim 11, wherein a state of the variable capacitor is associated with a process recipe in a process controller.

17. The plasma chamber as claimed in claim 11, further comprising a housing for the variable capacitor.

18. The plasma chamber as claimed in claim 17, wherein an output of the variable capacitor is connected to the housing.

19. The plasma chamber as claimed in claim 18, wherein the housing is connected to ground.

20. The plasma chamber as claimed in claim 16, wherein the process recipe is a common process recipe adjusted for a chamber-to-chamber variation.
